(19) United States
(12) Patent Application Publication
(10) Pub. No.: US 2012/0195336 A1
(43) Pub. Date: Aug. 2, 2012

(54) SEMICONDUCTOR LASER DEVICE IN WHICH AN EDGE-EMITTING LASER IS INTEGRATED WITH A REFLECTOR TO FORM A SURFACE-EMITTING SEMICONDUCTOR LASER DEVICE

(75) Inventors: Rui Yu Fang, Turin (IT); Guido Alberto Roggero, Turin (IT); Giuliana Morello, Turin (IT); Roberto Paoletti, Turin (IT); Michele Agresti, Turin (IT)

(73) Assignee: AVAGO TECHNOLOGIES FIBER IP (SINGAPORE) PTE. LTD., SINGAPORE (SG)

(21) Appl. No.: 13/018,581

(22) Filed: Feb. 1, 2011

(51) Int. Cl. H01S 5/183; H01L 33/60

(52) U.S. Cl. 372/45.01; 438/29; 257/E33.072

(57) ABSTRACT

A surface-emitting semiconductor laser device is provided that includes an edge-emitting laser formed in various layers of semiconductor material disposed on a semiconductor substrate, a polymer material disposed on the substrate laterally adjacent the layers in which the edge-emitting laser is formed, and a reflector formed in or on an angled side facet of the polymer material generally facing an exit end facet of the laser. Laser light passes out of the exit end facet propagates through the polymer material before being reflected by the reflector out of the device in a direction that is generally normal to the upper surface of the substrate.

### TECHNICAL FIELD OF THE INVENTION

The invention relates generally to semiconductor laser devices and, more particularly, to a semiconductor laser device in which an edge-emitting laser and a reflector are integrated together on the same chip to form a surface-emitting semiconductor laser device.

### BACKGROUND OF THE INVENTION

Semiconductor lasers are commonly used in optical transceivers for telecommunications and data communication networks. The lasers used in such optical transceivers are commonly of the edge-emitting type. Edge-emitting lasers for optical transceivers are fabricated on semiconductor wafers using standard photolithographic and epitaxial methods, diced into chips, and portions of each chip coated with reflective and anti-reflective coatings. The finished chips can then be tested. It would be desirable to minimize the number of manufacturing steps as well as to enhance testability.

Vertical Cavity Surface Emitting Lasers (VCSELs) are often preferred by end-users because of their high coupling efficiency with optical fibers without the need to provide beam shape correction, thus reducing test/packaging costs. Currently, however, some VCSELs have problems with regard to single-mode yield control when manufactured for very high speed operation.

Efforts have also been made in the industry to convert an edge-emitting device into a vertical-emitting device. For example, U.S. Pat. No. 7,245,645 B2 discloses one or both of the laser facets etched at 45° angles to form a 45° minor that reflects the laser beam vertically. In this solution, however, the 45° minor is within the laser cavity. The inclusion of an etched mirror inside of the laser cavity requires performing a high quality facet etching process during fabrication. Any facet damage that occurs during the facet etching process can result in reliability issues, especially when operating under high power.

U.S. Pat. No. 5,671,243 discloses using conventional 90° laser facets that are outside of the lasing cavity, but in the same chip there is a reflection minor that turns the beam towards in the direction of the surface. Because the minor is formed in the active layers, the mirror height and position cannot be adjusted. For this reason, it is difficult or impossible to optimize the structure.

U.S. Pat. No. 7,450,621 to the assignee of the present application discloses a solution that overcomes many of the aforementioned difficulties. This patent discloses a semiconductor device in which a diffractive lens is integrated with an edge-emitting laser on the same chip. The diffractive lens is monolithically integrated with the edge-emitting laser on an indium phosphide (InP) substrate material. The monolithic integration of a diffractive lens on the same chip in which the edge-emitting laser is integrated requires the performance of multiple Electron Beam Lithography (EBL) exposure and dry etching processes, which increases device fabrication costs.

It would be desirable to provide a surface-emitting semiconductor device that implements an edge-emitting laser to obtain the benefits associated therewith and that is economical to manufacture and test.

### SUMMARY OF THE INVENTION

The invention is directed to a surface-emitting semiconductor laser device and a method for fabricating the device. The device comprises a substrate having an upper surface and a lower surface, a plurality of semiconductor layers disposed on the substrate, an edge-emitting laser formed in the semiconductor layers for producing laser light of a lasing wavelength, a channel formed in the semiconductor layers, a polymer material disposed in the channel, and a reflector located on the angled side facet of the polymer material generally facing the second end facet of the laser. During operations of the laser, at least a portion of the laser light that passes out of the second end facet is reflected by the reflector in a direction generally normal to the upper surface of the substrate.

The fabrication method comprises depositing or growing a plurality of semiconductor layers on a substrate, forming an edge-emitting laser in one or more of the semiconductor layers for producing laser light of a lasing wavelength, forming a channel in the semiconductor layers, and disposing a polymer material in the channel, forming a reflector on the angled side facet of the polymer material generally facing the second end facet of the laser.

These and other features and advantages of the invention will become apparent from the following description, drawings and claims.

### BRIEF DESCRIPTION OF THE DRAWINGS

FIG. 1A illustrates a top perspective view of the surface-emitting semiconductor laser device in accordance with an exemplary, or illustrative, embodiment.

FIG. 1B illustrates a side plan view of the surface-emitting semiconductor laser device shown in FIG. 1A taken along A-A′ line of FIG. 1A.

FIG. 2A illustrates a top perspective view of the surface-emitting semiconductor laser device in accordance with another illustrative embodiment.

FIG. 2B illustrates a side plan view of the surface-emitting semiconductor laser device shown in FIG. 2A taken along A-A′ line of FIG. 2A.

FIG. 3 is a top plan view of a portion of the surface-emitting semiconductor laser device shown in FIGS. 2A and 2B.

FIGS. 4A-4H together illustrate a sequence of process steps that may be used to fabricate the surface-emitting semiconductor laser device shown in FIGS. 1A-2B.

### DETAILED DESCRIPTION OF AN ILLUSTRATIVE EMBODIMENT

The invention is directed to a surface-emitting semiconductor laser device in which an edge-emitting laser formed in a semiconductor material and a reflector formed in a polymer material are integrated together in the surface-emitting semiconductor laser device. The device includes an edge-emitting laser formed in various layers of semiconductor material disposed on a semiconductor substrate, a polymer material disposed on the substrate laterally adjacent the layers in which the edge-emitting laser is formed, and a reflector formed in or on an angled surface of the polymer material facing the laser channel of the edge-emitting laser. Laser light propagating out of the laser channel of the edge-emitting laser is reflected by the reflector at an angle that is generally orthogonal to the angle of incidence of the laser light on the reflector to cause the light to be directed out of the surface-emitting semiconductor laser device in a direction generally normal to its surface.

Forming the reflector in the polymer material rather than monolithically in a semiconductor material provides advantages with respect to choosing the height and position of the reflector for optimization. Another advantage is that the angled surface of the polymer material is formed by an etching process that is separate from the etching process that is used to etch the semiconductor materials and that uses a different gas system than that which is used to etch the semiconductor materials. This feature provides an additional degree of freedom in designing the reflector. In addition, because the reflector can be formed in the polymer material through a coating process that is performed at the wafer level, all of the surface-emitting semiconductor laser devices can be tested while on the wafer, i.e., before singulation is performed. This latter feature also reduces manufacturing costs.

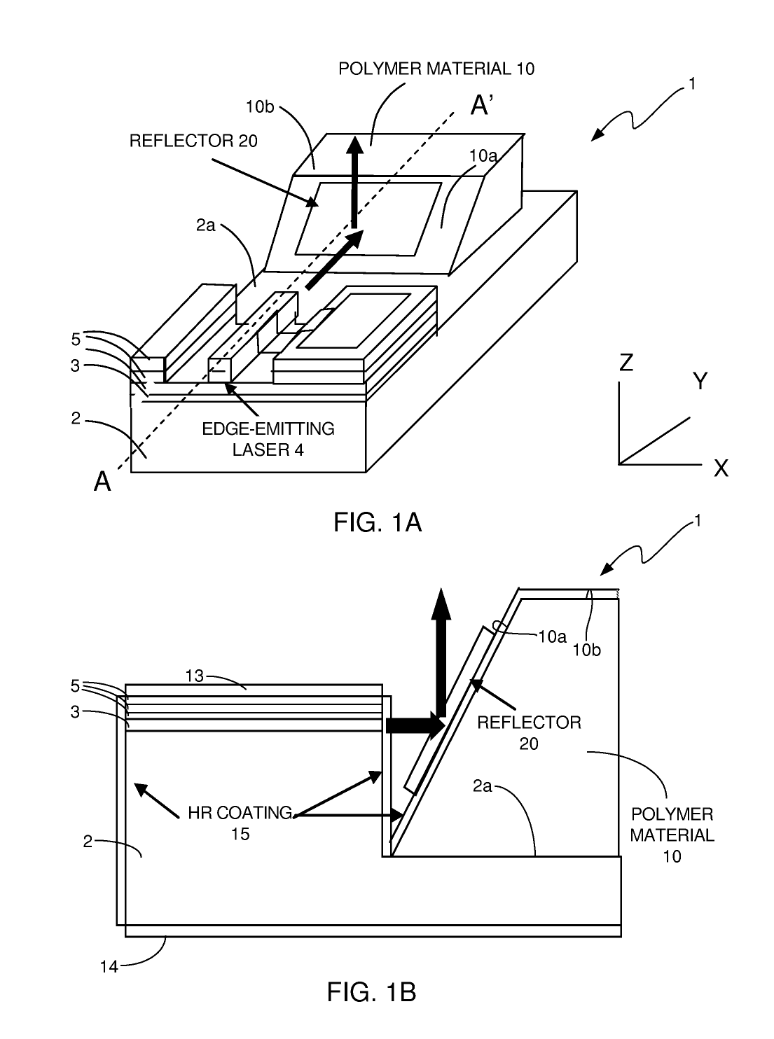

FIG. 1A illustrates a top perspective view of the surface-emitting semiconductor laser device 1 in accordance with an exemplary, or illustrative, embodiment. FIG. 1B illustrates a side plan view of the surface-emitting semiconductor laser device 1 shown in FIG. 1B taken along A-A′ line of FIG. 1A. The semiconductor laser device 1 in accordance with this illustrative embodiment will now be described with reference to FIGS. 1A and 1B. The device 1 includes a semiconductor substrate 2, a buffer layer 3 disposed on the upper surface 2a of the substrate 2, an edge-emitting laser 4 formed in one or more multi quantum well (MQW) active layers and cladding and contact layers 5 that are disposed on top of the buffer layer 3, a polymer material 10 disposed on the upper surface 2a of the substrate 2 laterally adjacent the edge-emitting laser 4, and a reflector 20 disposed on an angled side facet 10a of the polymer material 10. If the device 1 is viewed with reference to an X, Y, Z Cartesian Coordinate System defined by X-, Y- and Z-axes, the angled side facet 10a is typically, but not necessarily, inclined at a 45° angle relative to the X-Y plane.

A p-metal contact 13 (shown in FIG. 1B, but not in FIG. 1A) is formed on top of the uppermost layer of the device 1 above the layers 5. An n-metal contact 14 (shown in FIG. 1B, but not in FIG. 1A) is formed on the lower surface of the substrate 2. In accordance with the illustrative embodiment of FIGS. 1A and 1B, the device 1 is a Fabry-Perot (F-P) laser device. In F-P laser devices, a highly reflective (HR) coating is needed on the end facets of the edge-emitting laser in order to minimize facet loss. In FIG. 1B, the layer referenced by reference numeral 15 corresponds to the HR coating. The HR coating 15 has a reflectivity value that is selected based on the cavity length of the edge-emitting laser 4. If the reflectivity value of the HR coating 15 is sufficiently high, then the reflector 20, which is typically a thin layer of metal, can be eliminated because the HR coating 15 will act as the reflector to reflect the laser light emitted by the edge-emitting laser 4 out of the device 1 in a direction generally normal to the upper surface 2a of the substrate 2.

The material of which the substrate 2 is made may be, for example, doped indium phosphide (InP) or gallium arsenide (GaAs). For exemplary purposes, it will be assumed that the semiconductor substrate 2 is made of InP. It will also be assumed that the buffer layer 3 is made of n-type InP. The layers 5 include an MQW active region, one or more p-type InP spacer layers, infill layers, and cladding and contact layers, which are typically grown using a known MOCVD technique. Persons skilled in the art will understand the manner in which such additional layers may be included in the device 1.

The edge-emitting laser 4 is typically a ridge structure, such as a reverse-mesa ridge structure, as is known in the art. Methods that may be used to form such a ridge structure are discussed in detail in U.S. Pat. No. 7,539,228, which is assigned to the assignee of the present application and which is incorporated by reference herein in its entirety. As disclosed in this patent, the ridge structure may be etched using convention techniques described in the background of the patent, or grown using techniques described in the detailed description the patent.

During operations, the edge-emitting laser 4 emits a light beam generally along an axis that is parallel to the plane of the substrate 2. The laser beam passes out of the exit facet of the laser 4 and is incident on the reflector 20 (or on the HR coating 15 if the reflector 20 is not needed) an angle of typically about 45° relative to the angled surface 10a of the polymer material 10. The laser beam is then reflected by the reflector 20 (or by the HR coating 15) in a direction generally toward an upper surface 10b of the polymer material 10, which is generally normal to the upper surface 2a of the substrate 2. Accordingly, a beam emerges from the device 1 oriented along an axis that is substantially perpendicular to the upper surface 2a of the substrate 2, i.e., substantially perpendicular to the upper surfaces of the device 1. For this reason, the device 1 is referred to herein as a “surface-emitting” device.

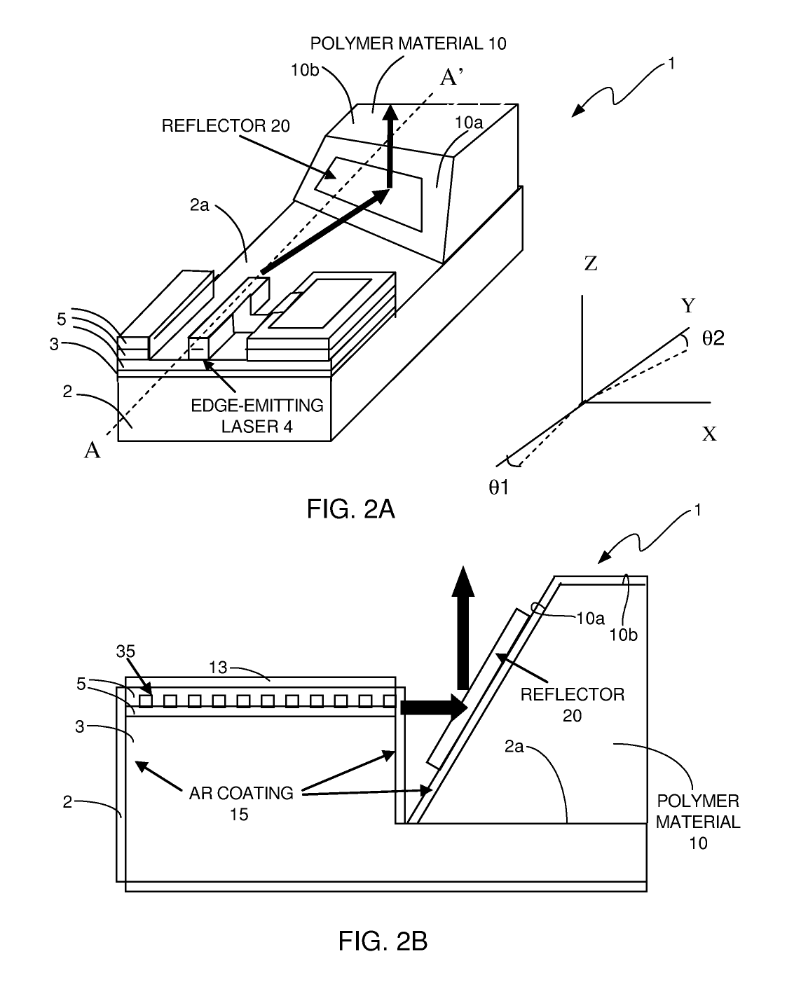

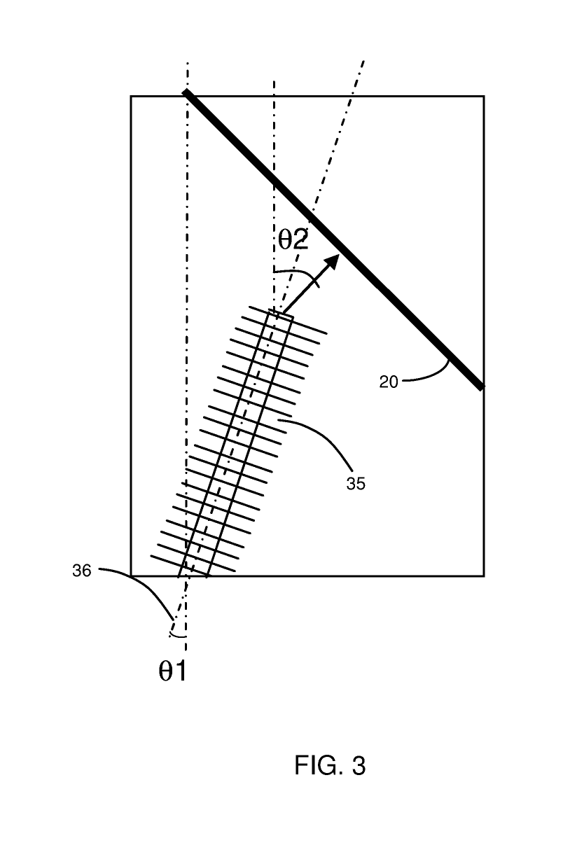

FIG. 2A illustrates a top perspective view of the surface-emitting semiconductor laser device 30 in accordance with another exemplary, or illustrative, embodiment. FIG. 2B illustrates a side plan view of the surface-emitting semiconductor laser device 30 shown in FIG. 2B taken along line A-A′ of FIG. 2A. FIG. 3 illustrates a top plan view of the device 30 shown in FIGS. 2A and 2B. The semiconductor laser device 30 in accordance with this illustrative embodiment will now be described with reference to FIGS. 2A, 2B and 3. Because many of the elements or features of the device 30 shown in FIGS. 2A-3 may be the same as the elements or features of the device 1 shown in FIGS. 1A and 1B, like reference numerals are used in these figures to refer to like features or elements.

The device 30 includes a semiconductor substrate 2, a buffer layer 3 disposed on the upper surface of the substrate 2, an edge-emitting laser 4 formed in one or more layers 5 that are disposed on top of the buffer layer 3, a polymer material 10 disposed on the upper surface of the substrate 2 laterally adjacent the edge-emitting laser 4, and a reflector 20 disposed on an angled side facet 10a of the polymer material 10. In accordance with the illustrative embodiment of FIGS. 2A and 2B, the device 30 is a distributed feedback (DFB) semiconductor laser device rather than an F-P semiconductor laser device. As such, to provide optical feedback, a grating 35 is formed in the MQW layers of the layers 5 in the case of a gain-coupled DFB or outside the MQW layers of layers 5 in the case of an index-guided DFB. In DFB lasers, it is common to tilt the waveguide of the edge-emitting laser to relative to the Y-axis to reduce reflection at the exit facet of the laser. For this reason, in accordance with the illustrative embodiment shown in FIGS. 2A and 2B, the optical axis 36 of the grating 35 is tilted with reference to the Y-axis by a first angle, θ1, such that laser light propagating through the waveguide passes out of the exit facet at a second angle, θ2, relative to the Y-axis due to refraction in accordance with Snell's Law. The value of θ1 typically ranges from about 5° to 15° and θ2 typically ranges from about 25° to about 35°, although the invention is not limited to any particular ranges of angles.

As in the embodiment represented by FIGS. 1A and 1B, the angled side facet 10a is typically inclined at a 45° angle relative to the X-Y plane. In accordance with this embodiment, the plane of the angled side facet 10a is also rotated about the Z-axis by an third angle, θ3, that is equal to the second angle θ2 so that the laser light is incident on the reflector 20 at a 45° angle relative to both the Z-axis and the X-Y plane.

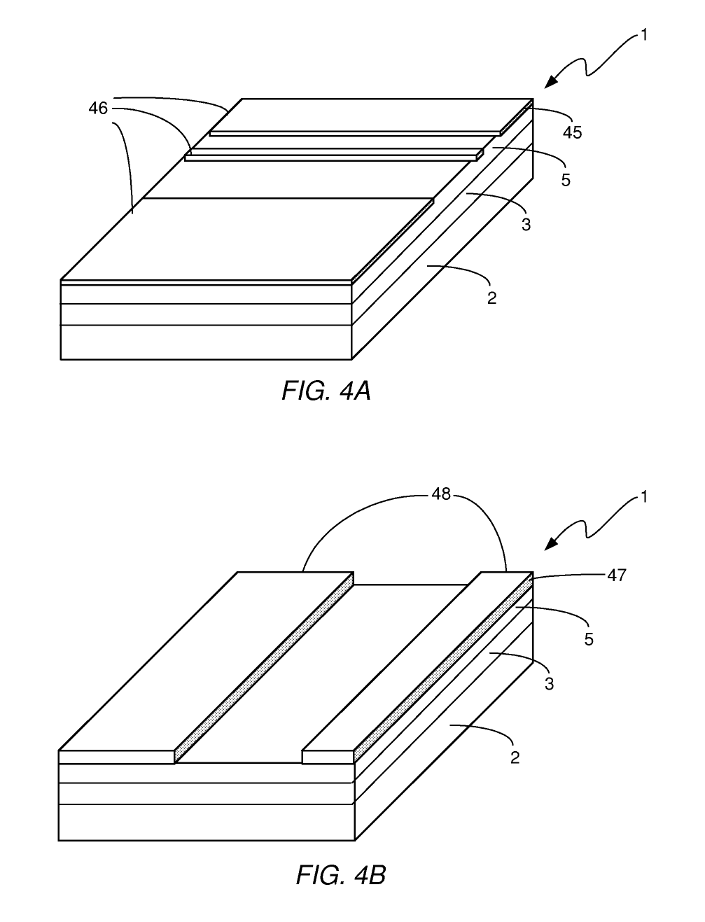

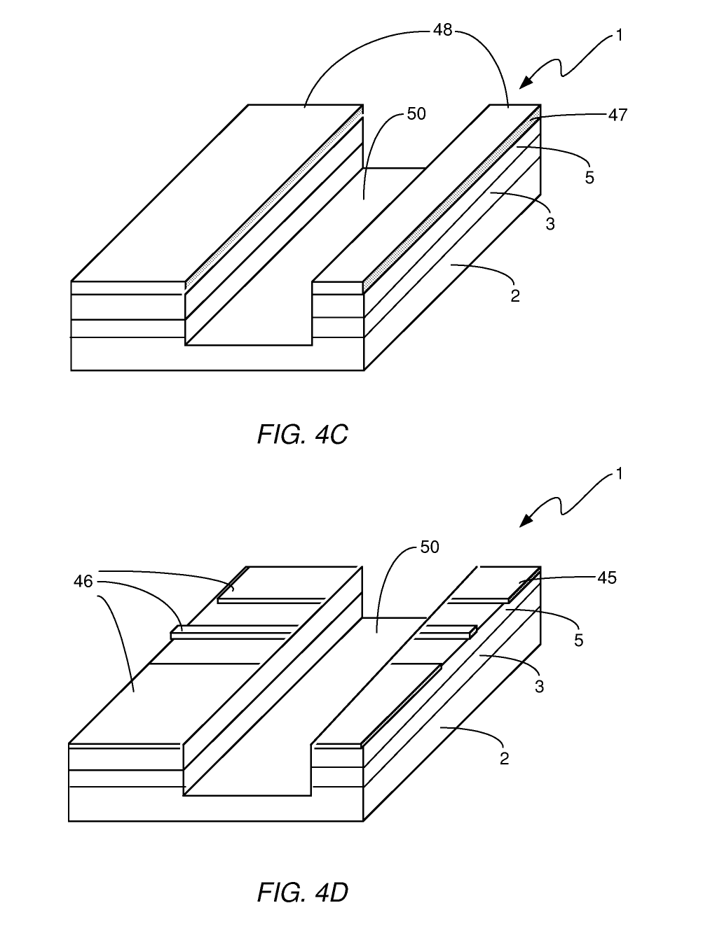

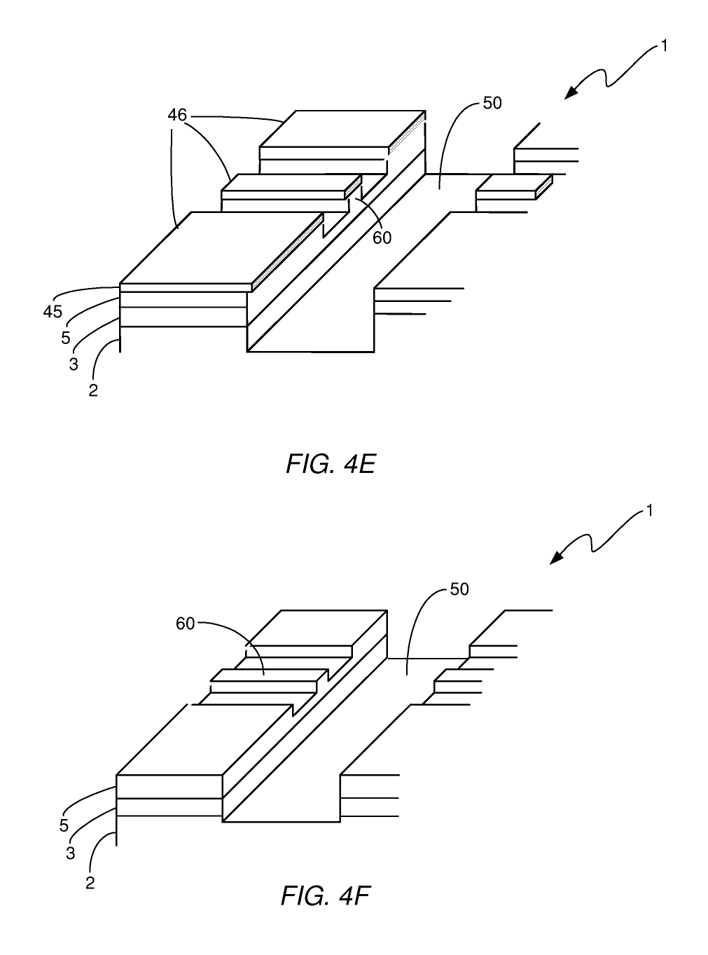

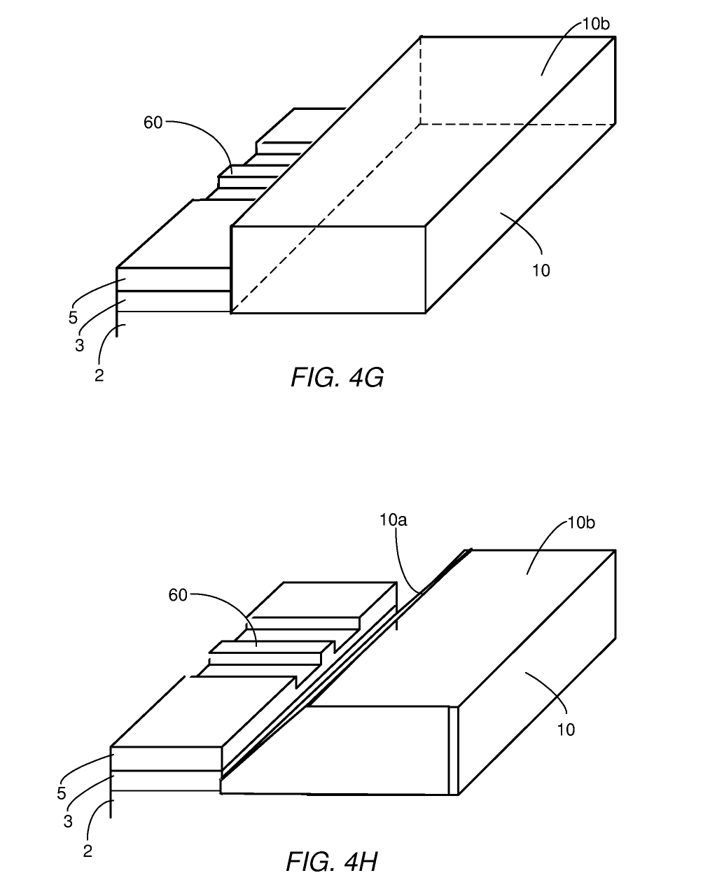

FIGS. 4A-4H illustrate an example of a series of fabrication steps that may be used to fabricate the semiconductor laser devices 1 and 30 described above with reference to FIGS. 1A and 2B. The fabrication method will be described with reference to the device 1. The device 1 can be fabricated using conventional techniques. Additional steps not shown in FIGS. 4A-4H of the type commonly used in fabricating such devices can be included, as persons skilled in the art will readily appreciate. FIGS. 4A-4H are side perspective views of the device 1 shown in FIG. 1A at various stages during the fabrication process during which a channel 50 and a ridge structure 60 are formed in the device 1. Like numerals in FIGS. 1A-4H refer to like elements or features.

With reference to FIG. 4A, a first dielectric film 45, which is typically, but not necessarily, a silicon dioxide (SiO₂) film, is deposited on top of layers 5 (e.g., infill layers, cladding layers, contact layers). A ridge mask pattern 46 that will be used to define the location and configuration of a ridge structure is formed in the dielectric film 45 using conventional photolithography and dry etch techniques.

With reference to FIG. 4B, a second dielectric film 47, which is typically, but not necessarily, SiO₂, is deposited over the ridge mask pattern 46 and subjected to conventional photolithography and dry etch techniques to form a channel mask pattern 48 that will subsequently be used to define a channel. With reference to FIG. 4C, the device 1 shown in FIG. 4B is etched, typically by using an Inductive Coupled Plasma (ICP) etching process, to form the channel 50. An advantage of using an ICP etching process for this purpose is that it causes very little damage to layers that are adjacent the etched region while maintaining a good vertical sidewall profile for the vertical sides that define the channel 50.

With reference to FIG. 4D, the channel mask pattern 48 shown in FIG. 4C is removed by using a Reactive Ion Etching (RIE) process, leaving only the ridge mask pattern 46 shown in FIG. 4A and the channel 50 shown in FIG. 4C. With reference to FIG. 4E, RIE or ICP is then used to form the ridge structure 60 without the need for a further photolithographic alignment. With reference to FIG. 4F, the etched ridge mask pattern 46 is then removed to expose the ridge 60.

With reference to FIG. 4G, the channel 50 is filled with the polymer material 10 by coating and etch-back processes. With reference to FIG. 4H, the angled side facet 10a is formed in or on the polymer material 10 via either standard photolithography/etch techniques or via an imprinting technique, the latter of which uses a master mask (not shown for purposes of clarity) having a shape and that is complementary to the desired shape of the polymer material 10 with the angled side facet 10a formed therein. The imprinting technique is a low-cost fabrication technique that allows the overall cost associated with fabricating the device 1 to be greatly reduced. After the angled side facet 10a has been formed in the polymer material 10, as shown in FIG. 4H, the HR coating 15, the p-metal 13, and the reflector 20 (if needed) are then formed on the device 1 (FIGS. 1A and 1B). For purposes of clarity, the contacts 13 and 14, the HR coating 15 and the reflector 20 are not shown in FIG. 4H.

The fabrication process described above with reference to FIGS. 4A-4H to form the device 1 is essentially the same as the process that would be used to form the device 30, except that additional processing steps are used to form the grating 35 (FIG. 2B) and some of the other steps are altered to tilt the waveguide of the edge-emitting laser 4, and an AR coating rather than an HR coating is used in the device 30. Persons skilled in the art will understand the manner in which these additional steps are performed. Therefore, in the interest of brevity, these additional steps will not be described herein.

The invention has been described with reference to a few illustrative or exemplary embodiments for the purposes of describing the principles and concepts of the invention. The invention, however, is not limited to these embodiments, as will be understood by persons skilled in the art in view of the description provided herein. For example, while the substrate 2 and other layers of the devices 1 and 30 have been described as using InP, the substrate 2 and the other layers may comprise any suitable material, such as a GaAs substrate, aluminum gallium (AlGa), aluminum gallium indium arsenide (AlGaInAs), etc. In addition, various other metal configurations may be used for the p-metal and n-metal contacts. The surface-emitting semiconductor laser devices 1 and 30 may operate as single transverse mode or multimode lasers, or as a longitudinally single mode laser. Those skilled in the art will understand that various modifications may be made to the embodiments described herein and that it is intended that the present invention cover all such modifications and variations.

What is claimed is:

1. A surface-emitting semiconductor laser device comprising:
a substrate having an upper surface and a lower surface;
a plurality of semiconductor layers comprising at least a lowermost layer and an uppermost layer, wherein the lowermost layer is disposed on the upper surface of the substrate, said plurality of semiconductor layers having an edge-emitting laser formed therein for producing laser light of a lasing wavelength when the laser is activated, the laser having first and second end facets, wherein the laser light of the lasing wavelength passes out of the laser through the second end facet when the laser is activated;
a channel formed in one or more of said plurality of semiconductor layers;
a polymer material disposed in the channel, the polymer material including at least a lower surface and an angled side facet, the lower surface of the polymer material being in contact with the channel, the angled side facet generally facing the second end facet of the edge-emitting laser; and
a reflector disposed on the angled side facet of the polymer material, wherein at least a portion of the laser light that passes out of the second end facet of the edge-emitting laser is incident on the reflector and is reflected by the reflector in a direction generally normal to the upper surface of the substrate.

2. The surface-emitting semiconductor laser device of claim 1, wherein the reflector comprises a layer of metal disposed on the angled side facet of the polymer material.

3. The surface-emitting semiconductor laser device of claim 2, wherein the edge-emitting laser is a Fabry-Perot (F-P) laser, and wherein the layer of metal is part of a highly-reflective (HR) coating that coats the first and second end facets of the edge-emitting laser and the angled side surface of the polymer material.

4. The surface-emitting semiconductor laser device of claim 2, wherein the edge-emitting laser is a distributed feedback (DFB) laser, and wherein the first and second end facets of the edge-emitting laser and the angled side surface of the polymer material are coated with an anti-reflective (AR) coating, and wherein the reflector is disposed on the AR coating.

5. The surface-emitting semiconductor laser device of claim 2, wherein the edge-emitting laser is a Fabry-Perot (FP) laser, and wherein the first and second end facets of the edge-emitting laser and the angled side surface of the polymer material are coated with a highly-reflective (HR) coating, and wherein the layer of metal comprising the reflector is disposed on the HR coating.

6. The surface-emitting semiconductor laser device of claim 1, wherein the angled side facet of the polymer material is a generally planar surface that is at an angle to the upper surface of the substrate.

7. The surface-emitting semiconductor laser device of claim 6, wherein the angle is approximately 45 degrees.

8. The surface-emitting semiconductor laser device of claim 7, wherein laser light passing out of the second end facet propagates along a waveguide of the edge-emitting laser, the waveguide having an optical axis that is at an angle of approximately 45 degrees to the generally planar surface of the angled side facet.

9. The surface-emitting semiconductor laser device of claim 8, wherein the optical axis of the waveguide of the edge-emitting laser is generally parallel to the upper surface of the substrate.

10. A method of fabricating a surface-emitting semiconductor laser device, the method comprising:
on a substrate, depositing or growing a plurality of semiconductor layers comprising at least a lowermost layer and an uppermost layer, wherein the lowermost layer is disposed on the upper surface of the substrate;
in one or more of said plurality of semiconductor layers, forming an edge-emitting laser for producing laser light of a lasing wavelength, the laser having first and second end facets, wherein if the laser is activated, laser light produced by the laser passes out of the laser through the second end facet;
forming a channel in said plurality of semiconductor layers;
disposing a polymer material in the channel, the polymer material including at least a lower surface and an angled side facet, the angled side facet generally facing the second end facet of the edge-emitting laser; and
forming a reflector on the angled side facet of the polymer material.

11. The method of claim 10, wherein the reflector comprises a layer of metal.

12. The method of claim 11, wherein the edge-emitting laser is a Fabry-Perot (F-P) laser, the method further comprises:
prior to forming the reflector, coating the first and second end facets of the edge-emitting laser and the angled side surface of the polymer material with a highly-reflective (HR) coating, and wherein the reflector is disposed on the HR coating.

13. The method of claim 11, wherein the edge-emitting laser is a distributed feedback (DFB) laser, the method further comprising:
prior to forming the reflector, coating the first and second end facets of the edge-emitting laser and the angled side surface of the polymer material with an anti-reflective (AR) coating, and wherein the reflector is disposed on the AR coating.

14. The method of claim 11, wherein the edge-emitting laser is a Fabry-Perot (FP) laser, and wherein the step of forming the reflector includes coating the first and second end facets of the edge-emitting laser and the angled side surface of the polymer material with a highly-reflective (HR) coating, and wherein the layer of metal comprising the reflector is disposed on the HR coating.

15. The method of claim 10, wherein the angled side facet of the polymer material is a generally planar surface that is at an angle to the upper surface of the substrate.

16. The method of claim 15, wherein the angle is approximately 45 degrees.

17. The method of claim 16, wherein the edge-emitting laser includes a waveguide having an optical axis that is generally parallel to the upper surface of the substrate and at an angle of about 45 degrees to the generally planar surface of the angled side facet.
